(19) United States
(12) Patent Application Publication
(10) Pub. No.: US 2010/0044775 A1
(43) Pub. Date: Feb. 25, 2010

(54) SEMICONDUCTOR MEMORY DEVICE AND SEMICONDUCTOR DEVICE

(76) Inventor: Hiroshi Sunamura, Tokyo (JP)

Correspondence Address: Mr. Jackson Chen, 6535 N. STATE HWY 161, IRVING, TX, 75039, US

(21) Appl. No.: 12/518,148

(22) PCT Filed: Dec. 7, 2007
(86) PCT No.: PCT/JP2007/073726

§ 371 Date: Jun. 8, 2009

(30) Foreign Application Priority Data
Dec. 7, 2006 (JP) 2006-330172

(51) Int. Cl. H01L 29/792; H01L 29/78

(52) U.S. Cl. 257/324; 257/314; 257/E29.309; 257/E29.255; 977/943

(57) ABSTRACT

Provided is a semiconductor memory device that can retain information by trapping electric charges into a trap level in a gate insulating film. The information retention capacity is improved by restricting lateral diffusion of electric charges. The semiconductor memory device is provided with a semiconductor substrate (11), first and second impurities diffusion layers (12; 13) disposed in the semiconductor substrate, a gate insulating film (15) disposed on the semiconductor substrate, and a first gate electrode (16) disposed on the semiconductor substrate by way of the gate insulating film (15). The gate insulating film (15) has a silicon oxide film (14) that contains impurities which tend to combine with oxygen in the silicon oxide film and which are discrete at an atomic level.

### TECHNICAL FIELD OF THE INVENTION

The present invention is directed to a semiconductor memory device and a semiconductor device, and more particularly to a semiconductor memory device that can retain information by trapping charges into a trap level in a gate insulating film, and to a semiconductor device in which the semiconductor memory device is mounted.

### DESCRIPTION OF THE RELATED ART

In order to sufficiently provide the current information relating to the present invention, any available references such as patent publications, laid-open patent applications and scientific literatures cited or identified in the present application are hereby incorporated by reference in their entirety.

Recently, the demand for a non-volatile memory has increased as a rewritable semiconductor memory device. With regard to a flash memory which is a typical example of a non-volatile memory, a flash memory that employs a floating gate is in the mainstream. However, a thinner layer of the tunnel gate oxide film is considered to be difficult to achieve, which means that refinement is about to hit its limit. Meanwhile, thinning of the Equivalent Oxide Thickness (EOT) of a memory cell is of key importance for increasing the read current of the memory cell.

As a technique to overcome the limit in the layer thinning, a trap-type semiconductor memory device has received attention recently. The trap-type semiconductor memory device disposes an insulate film having a trap level on a tunnel gate oxide film disposed on a semiconductor substrate, traps charges into a trap level that exists in the insulating film, whereby information is stored.

Representative examples of a trap-type semiconductor memory device that assumes a trap level in an insulating film as a memory node include MNOS (Metal-Nitride-Oxide-Semiconductor) memory, and MONOS (Metal-Oxide-Nitride-Oxide-Semiconductor) memory. In a MNOS memory and a MONOS memory, a silicon nitride film (N) is used as insulating film having a trap level. The structure and the programming method of a MONOS-type semiconductor memory device are described in, for example, the Japanese Laid-open Patent Publication No. 2001-156189.

It is believed that a silicon nitride film that forms a trap-containing layer of the trap-type semiconductor memory device should usually be equal to and greater than 4 nanometers in thickness. However, the thickness of the silicon nitride film acts as a limit factor against thinning of EOT layers. Further, there is an attempt to employ a high-k material as a substitute for a silicon nitride film; however, the thickness of the high-k film also acts as a limit factor against thinning of EOT layers. Besides, in the case of a MNOS memory and a MONOS memory, a lateral movement of a carrier becomes likely to occur when the trap density is high. Hence, a long-term retention in a high-temperature condition (150 degrees Centigrade) is problematic.

In contrast, some other inventions employ nanocrystals embedded in a silicon oxide film as a trap-containing layer in place of a dielectric thin film such as a silicon nitride film (for example, see the Japanese Laid-open Patent Publication No. 2004-055969 and the Japanese Laid-open Patent Publication No.□ 2002-222875). As a material for the nanocrystals, a so-called conductive material is employed which is a metal represented by a doped silicon or tungsten, whereby there is a high probability that the EOT can be produced thinner. FIG. 1 is a cross-sectional view of the semiconductor memory device as disclosed in the Japanese Laid-open Patent Publication No. 2004-055969 and the Japanese Laid-open Patent Publication No. 2002-222875. A nanocrystal-type semiconductor memory device 50 comprises: impurities diffusion layers 52, 53 that function as source and drain regions disposed on a surface region of a silicon substrate 51; and a gate electrode 56 consisting of, for example, polysilicon disposed, by way of a silicon oxide film 55, on a channel region provided between the impurities diffusion layers 52, 53. Further, nanocrystals 54 which are a charge storing layer are embedded in the silicon oxide film 55, the charge storing layer including tungsten. The semiconductor memory device 50 has a MIS-type transistor structure wherein an insulation structure (I) consisting of the silicon oxide film 55 in which a nano crystal 54 is embedded is sandwiched between the silicon substrate 51 and the gate electrode 56.

Following is the explanation of a write operation using a Channel Hot Electron (CHE) in a nanocrystal-type semiconductor memory device as shown in FIG. 1. Write operation by way of CHE injection is carried out by applying to between the impurities diffusion layers 52-52 (between source and drain) a voltage equal to and higher than a specific voltage, and further by applying to the gate electrode 56 a voltage equal to and higher than a specific voltage. For example, it is preferred that a source 52 is earthed, that a voltage equal to and greater than 3V is applied to the drain 53, and that a voltage equal to and greater than 4V is applied to the gale electrode 56.

The CHE injection method generates hot electrons that are locally generated in the vicinity of the drain 53, and the electrons that have been able to go over the energy barrier of the silicon oxide film 55 reach the discretely disposed tungsten-made nanocrystals 54, and are then trapped into the trap level of the nanocrystals 54. In the element structure, interchanging of voltages to be applied to a pair of source and drain allows for selective achievement of a local writing into the trap level of the nanocrystals 54 of the impurities diffusion layers 52 and 53, whereby a 2-bit memory operation is realized in a transistor-type memory element 50. Since the nanocrystals 54 are discretely disposed, movement of carriers is prevented, and thus the 2-bit information will be effectively retained. In contrast, an erase operation is carried out by neutralizing the electrons that have been accumulated by pouring, through an inter-band tunnel, a hot hole that has arisen in the proximity of the impurities diffusion layer 52 or 53 into the nanocrystals 54. The hot hole is generated by applying a voltage equal to and greater than a specific voltage to between the source-drain, and further applying a voltage equal to and greater than a specific voltage in absolute value to the gate electrode 56. For example, an option is that the source is earthed, that a voltage equal to and greater than 3V is applied to the drain 53, and that a voltage not exceeding −4V is applied to the gate electrode 56. Meanwhile, the foregoing operation method is directed to an n-type nanocrystal-type semiconductor memory device wherein the silicon substrate 51 is of p-type and the impurities diffusion layers 52, 53, which dispose the source-drain region, are of n-type. However, the role of electrons and holes can be exchanged even in a p-type nanocrystal-type semiconductor memory device wherein the silicon substrate 51 is of n-type and the impurities diffusion layer 52, 53, which dispose the source-drain region, are of p-type.

### DISCLOSURE OF THE INVENTION

### Problem to be Solved by the Invention

The preset inventions et al. have been taking charge of research and development of semiconductor memory devices, and conducting a variety of studies relating to performance improvement of semiconductor memory devices. In recent years, the main focus of the study conducted by the inventors et al. has been specifically placed on a MONOS-type semiconductor memory device. In particular, the inventors have believed that higher read speed necessarily requires thinning of the EOT by which the read current of a memory cell becomes greater, and have studied the EOT thinning technology, and in particular, the trap memory structure having nanocrystals. A number of studies led the inventors to encounter several difficulties. Following are among the difficulties which seem to be of key importance.

Experimental production of the conventional structures for study revealed that the desired retention properties were not achievable. In particular, the experimental production caused conspicuous exchanges of electric charges among nanocrystals. Even though the inventors tried to locally write electric charges using the CHE injection for 2-bit operation, the quantity of the charges was averaged on a plane after storage in a high temperature condition whereby the 2-bit information disappeared.

The lateral diffusion of electric charges seen here causes a phenomenon which is a problem also for MONOS-type semiconductor memory devices which employ a silicon nitride film as a trap film. The greater the trap density is, the more likely the lateral diffusion is to occur. In order to prevent the lateral diffusion, an experiment was conducted wherein a trap film was physically separated into two segments closer to the source and drain ends for 2-bit operation. However, this approach greatly increases the number of processes necessary for elements preparation, leading to higher cost. Meanwhile, the original concept of the nanocrystals was to prevent lateral diffusion by taking advantage of the fact that the nanocrystals that store electric charges are dispersed in plane. However, the studies conducted by the present invention et al. exposed the lateral diffusion, and did not bring about the solution of the problem.

On the other hand, it was found that the influence of nanocrystals, or matters having a certain amount of size, toward the surrounding insulating film is not negligible. A nanocrystal is usually of a size of 3 nanometers or greater, which size is equal to and greater than a half of the film thickness of a tunnel oxidation film and of an upper oxidation film. Hence, unevenness is generated on the oxidation film surrounding the nanocrystals. Further, due to the electric field density resulting from the shape of a nanocrystal, it became necessary to produce a thicker oxidation film, contrary to the original intent, such that the reliability of a memory cell is ensured. It was thus difficult for the above-described conventional art to manufacture a flash memory having a thinned EOT, and in order to increase the read current of a flash memory cell, a trap memory having a trap film disposed by way of a new technique was required.

The semiconductor memory device as defined in the present invention is to solve the problems revealed in manufacturing a nanocrystal-type semiconductor memory device according to the above-described prior art.

The present invention is directed to a semiconductor memory device that can retain information by trapping electric charges into a trap level in a gate insulating film. It is an object of the invention to improve the information retention capacity at an elevated temperature by restricting the lateral diffusion of electric charges that has resulted in loss of stored information when retaining 2-bit information in a conventional element structure, and to provide with a structure that achieves low-cost production and high-speed reading.

### Means of Solving Problems

Following are the representative aspects of the invention as disclosed in the present application that is intended to achieve the above-described object.

The semiconductor memory device as disclosed in the present invention is a semiconductor memory device that conducts a memory operation by trapping electric charges into a gate insulating film, wherein the gate insulating film has a first insulating film that contains first impurities which tend to combine with oxygen in the insulating film and which are discrete at an atomic level.

The semiconductor memory device as disclosed in the present invention is a semiconductor memory device that conducts a memory operation by trapping electric charges into a gate insulating film, the semiconductor memory device comprising: a semiconductor substrate; first and second impurities diffusion layers disposed in the semiconductor substrate; a gate insulating film disposed on the semiconductor substrate; and a first gate electrode disposed on the semiconductor substrate by way of the gate insulating film. The gate insulating film has a first insulating film that contains first impurities which tend to combine with oxygen in the insulating film and which are discrete at an atomic level.

Further, the semiconductor memory device as disclosed in the present invention comprises a semiconductor substrate, first and second impurities diffusion layers disposed in the semiconductor substrate, a gate insulating film disposed on the semiconductor substrate, and a first gate electrode disposed on the semiconductor substrate by way of the gate insulating film. The gate insulating film has a first insulating film that contains first impurities which tend to combine with oxygen in the insulating film and which are discrete at an atomic level, and, on a top and a bottom of the first insulating film, a silicon oxide film that does not contain the first impurities.

Still further, the semiconductor memory device as disclosed in the present invention comprises a semiconductor substrate, first and second impurities diffusion layers disposed in the semiconductor substrate, a gate insulating film disposed on the semiconductor substrate, and a first gate electrode disposed on the semiconductor substrate by way of the gate insulating film. The gate insulating film has a first insulating film that contains first impurities which tend to combine with oxygen in the insulating film and which are discrete at an atomic level, and, a second insulating film that contains second impurities different from the first impurities, the second insulating film being disposed immediately on a top of the first insulating film.

Still more further, the semiconductor memory device as disclosed in the present invention comprises a semiconductor substrate, first and second impurities diffusion layers disposed in the semiconductor substrate, a gate insulating film disposed on the semiconductor substrate, and a first gate electrode disposed on the semiconductor substrate by way of the gate insulating film. The gate insulating film has a first insulating film that contains first impurities which tend to combine with oxygen in the insulating film and which are discrete at an atomic level, and, a second insulating film that contains second impurities different from the first impurities, the second insulating film being disposed immediately on a top of the first insulating film; and further on a top and a bottom of the first and second insulating films, a silicon oxide film that does not contain the first or second impurities.

Still more further, in the semiconductor memory device as disclosed in the present invention, a density of charge trapping sites disposed by the first impurities is equal to and greater than 1×10² particles/cm² and less than 1×10¹⁴ particles/cm².

Still more further, in the semiconductor memory device as disclosed in the present invention, the first impurities which tend to combine with oxygen in a silicon oxide film and which are discrete at an atomic level consist of metal. In that case, the addition quantity of the first impurities as converted to film thickness of a metal layer is less than the thickness of a single atomic layer.

Still more further, in the semiconductor memory device as disclosed in the present invention, the first impurities, which tend to combine with oxygen in the silicon oxide film and which are discrete at an atomic level, consist of titan.

Still more further, in the semiconductor memory device as disclosed in the present invention, the second impurities consist of nitrogen.

Still more further, in the semiconductor memory device as disclosed in the present invention, the first insulating film consists of, or the first and second insulating films consist of, silicon oxide film.

Still more further, in the semiconductor memory device as disclosed in the present invention, a thin film comprising Al₂O₃, SiN or SiON is disposed on the first or second insulating film.

The above-described semiconductor memory device according to the present invention can be sufficiently achieved using the current method for disposition of an integrated circuit, and a semiconductor memory device can be manufactured without any problems so long as a conventional integrated circuit formation technology is employed. Forming a semiconductor memory device as disclosed in the present invention allows for manufacturing a semiconductor memory device that can sufficiently retain locally written electric charges for achieving 2-bit operation, in comparison with the conventional MNOS and MONOS memories.

### Advantageous Effect of the Invention

The approach as defined in the present invention enabled a semiconductor memory device that can retain information by trapping electric charges into a trap level in a gate insulating film to restrict the lateral diffusion that was conspicuous for the conventional element structure, at the Lime of retention in an elevated temperature condition, to fully retain the locally written electric charges, and to realize the 2-bit operation. Further, the structure as defined in the present invention enabled substantial reduction in cost of element production, and to realize high-speed reading.

### BRIEF DESCRIPTION OF THE DRAWINGS

FIG. 1 is a cross-sectional view showing a structure of a prior art semiconductor storage device.

FIG. 2 is a cross-sectional view showing a structure of the semiconductor memory device according to the first embodiment of the present invention.

FIG. 3(A) is a figure that shows the in-plane arrangement of nanocrystals in a prior art semiconductor memory device.

FIG. 3(B) is a figure that shows the in-plane arrangement of impurities discrete at an atomic level in a semiconductor memory device of the present invention, where the FIGS. 3(A) and 3(B) disposes a comparison of the prior art semiconductor memory device with the semiconductor memory device of the present invention.

FIGS. 4(A) to 4(G) are cross-sectional views showing, in a step-by-step order, the method for producing a semiconductor memory device according to the first embodiment of the present invention.

FIG. 5(A) is a graph showing the writing properties of a semiconductor memory device according to the first embodiment of the present invention.

FIG. 5(B) is a graph showing the writing properties of a prior art semiconductor memory device.

FIG. 6 is a graph showing the retention properties at 150 degrees Centigrade of the semiconductor memory device of the first embodiment of the present invention and the prior art semiconductor memory device.

FIGS. 7(A) to 7(G) are cross-sectional views showing, in a step-by-step order, the method for producing a semiconductor memory device according to the second embodiment of the present invention.

FIG. 8 is a cross-sectional view showing a structure of the semiconductor memory device according to the third embodiment of the present invention.

FIG. 9 is a cross-sectional view showing a structure of the semiconductor memory device according to the fourth embodiment of the present invention.

FIG. 10 is a cross-sectional view showing a structure of the semiconductor memory device according to the fifth embodiment of the present invention.

FIG. 11 is a cross-sectional view showing a structure of the semiconductor memory device according to the sixth embodiment of the present invention.

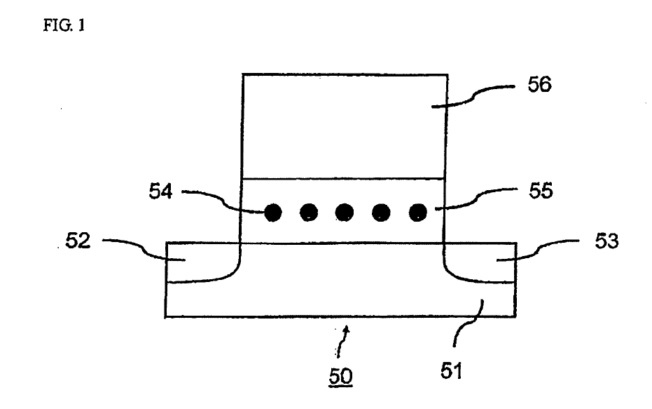

### EXPLANATION OF LETTERS OF NUMERALS

10 semiconductor memory device
11 semiconductor substrate (silicon substrate)
12 first impurities diffusion layer (source)
13 second impurities diffusion layer (drain)
14 silicon oxide film that contains impurities discrete at atomic level
15 gate insulating film
15a part of gate insulating film (silicon oxide film)
15b part of gate insulating film (silicon oxide film)
16 first gate electrode
16a gate electrode material layer
17 photoresist
17′ gate pattern-like photoresist
20 semiconductor memory device
21 semiconductor substrate (silicon substrate)
22 first impurities diffusion layer (source)
23 second impurities diffusion layer (drain)
24 silicon oxide film that contains first impurities discrete at atomic level
25 gate insulating film
25a part of gate insulating film (silicon oxide film)
25b part of gate insulating film (silicon oxide film)
26 first gate electrode
26a gate electrode material layer
27 photoresist
27′ gate pattern-like photoresist
28 second silicon oxide film that contains second impurities different from first impurities
30 semiconductor memory device
31 semiconductor substrate (silicon substrate)
32 first impurities diffusion layer (source)
33 second impurities diffusion layer (drain)
34 silicon oxide film that contains impurities discrete at atomic level
35a part of the gate insulating film (silicon oxide film)
35b part of the gate insulating film (silicon oxide film)
36 first gate electrode
36′ second gate electrode
39 second gate insulating film
40 sidewall insulating film
41 insulating film
50 semiconductor memory device
51 semiconductor substrate (silicon substrate)
52 impurities diffusion layer (source)
53 impurities diffusion layer (drain)
54 nanocrystal
55 silicon oxide film
56 first gate electrode

### BEST MODE FOR CARRYING OUT THE INVENTION

The preferred embodiments of the present invention will now be described with reference to the drawings attached hereto.

The present inventors et al. have repeatedly studied the semiconductor memory device aiming to solve the above-described problems. Before reverting to the preferred embodiments, the matters which the present inventors et al. studied in advance will be described. Meanwhile, as described above, the electric charges stored in a MONOS-type semiconductor memory device can be electrons and/or holes; the explanation now proceeds under the condition that electrons are the electric charges to be stored. Without doubt, the similar advantageous effects can be attained in the structure disclosed in the present invention even when holes are used as stored electric charges.

It is considered that the exchange of electric charges among nanocrystals that caused a problem during high-temperature retention results from the finite size of the nanocrystals. Although the detailed explanation will be reverted later in the present invention with reference to the drawings, in order to obtain the desired writing quantity, or a threshold shift, a nanocrystal having density of equal to and greater than a certain degree should be prepared such that a substantial quantity of trapped electric charges will be ensured. In that case, the distance between nanocrystals becomes relatively short, resulting in exchanges of electric charges among nanocrystals. It was thought that especially during high-temperature retention, in an elevated temperature condition, hopping of electric charges would be generated if the distance among nanocrystals is around 3 nanometers.

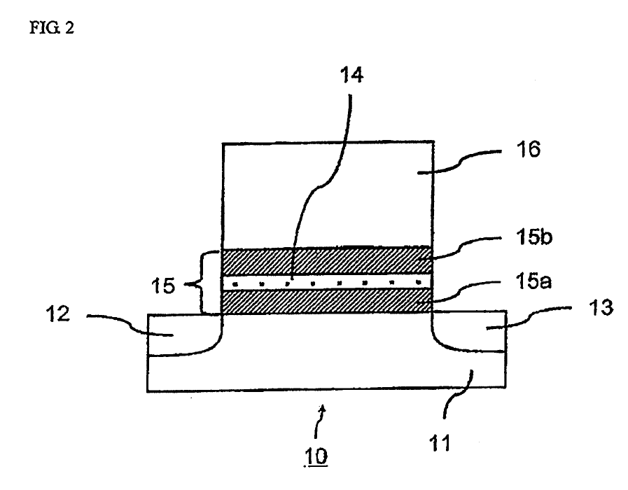

Hence, the present inventors et al. came to devise a structure of a semiconductor memory device as described hereinafter. The structures of a semiconductor memory device as disclosed in the present invention will be described with reference to FIG. 2. A semiconductor memory device 10 according to the first embodiment of the present invention comprises: a semiconductor substrate 11; a first and a second impurities diffusion layers 12 and 13 disposed in the semiconductor substrate 11; a gate insulating film 15 including a silicon oxide film 14 that contains impurities which tend to combine with oxygen in a silicon oxide film disposed on the semiconductor substrate 11 and which are discrete at an atomic level; and a first gate electrode 16 disposed on the semiconductor substrate 11 by way of the gate insulating film 15. Meanwhile, the silicon oxide film 14 that disposes the gate insulating film 15, and that contains impurities which tend to combine with oxygen and which are discrete at an atomic level can be substituted for an oxide film such as a silicon oxide nitride film, an alumina film, an aluminum silicate film and a hafnium silicate film, the oxide film containing impurities discrete at an atomic level. In case of using a silicon oxide nitride film or a metal silicate film, it is preferred to use a film having a composition of a large bandgap. More specifically, a film of a composition having 5 electron volts or greater is preferred. Besides, when using a film other than the silicon oxide film 14, not being limited to silicon oxide film, that contains impurities which tend to combine with oxygen and which are discrete at an atomic level, the film should be of an insulating material that can dispose a potential barrier which prevents breakaway of the electric charges stored in the silicon oxide film 15. The important point is that the gate insulating film 15 includes an oxide film that contains impurities which tend to combine with oxygen in an oxide film and which are discrete at an atomic level, whereas examples of the material for the gate insulating film 15 that sandwiches the oxide film that contains impurities which tend to combine with oxygen in an oxide film and which are discrete at an atomic level include a silicon oxide film, a high dielectric constant insulating film, and a combination thereof.

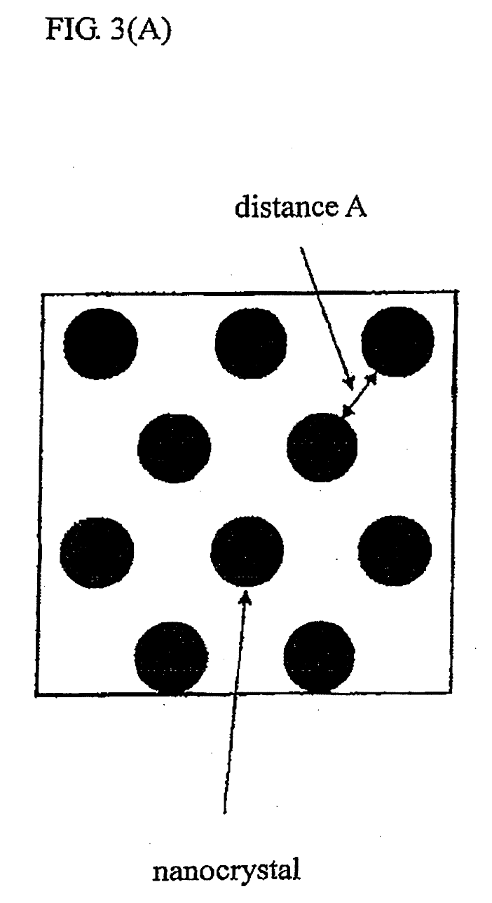

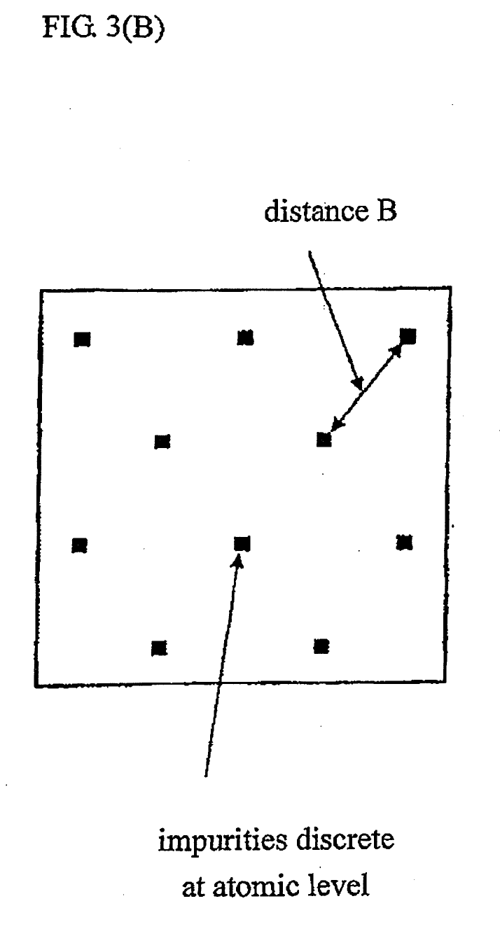

Following is the description of the novel advantageous effect to be achieved in the structure of a semiconductor memory device as disclosed in the present invention. FIG. 3(A) is a top plan view and a cross-sectional view of the charge storing layer in the conventional semiconductor memory device that employs nanocrystals as a charge storing layer. FIG. 3(B) is a top plan view and a cross-sectional view of the charge storing layer in the semiconductor memory device as disclosed in the present invention. In order to explicitly show the novel advantageous effect achieved in the structure of the semiconductor memory device as disclosed in the present invention, the density of the nanocrystal in FIG. 3(A) and the density of the impurities in FIG. 3(B) is rendered to be the same. Suppose that the number of electrons to be stored in each nanocrystal and each impurity is one (according to a report, the number of electron stored in one nanocrystal is one), the quantity of the capturable electric charges is the same, and the variation in the threshold voltage is the same in both FIGS. 3(A) and 3(B). Meanwhile, seeing the distance among the trap sites into which a charge is trapped, FIG. 3(A) indicates that the difference of the period in which nanocrystals are disposed from the diameter of nanocrystals accounts for the distance among nanocrystals (distance A in FIG. 3(A)); whereas FIG. 3(B) indicates that the period in which the impurities at an atomic level are disposed accounts for the distance among the impurities (distance B in FIG. 3(B)). It is apparent that there is a significant distance among the charge trapping sites in FIGS. 3(A) and 3(B). In other words, the semiconductor memory device as disclosed in the present invention can increase the distance among the charge trapping sites, while maintaining the capacity to trap electric charges at the similar level. Namely, the greater the distance is among the trapping sites, the less frequent the exchange of electric charges becomes among the trapping sites. As discussed above, introduction of the approach as disclosed in the present invention allows for reduction in exchange of electric charges that is generated among the charge trapping sites, resulting in restriction in the lateral diffusion of electric charges.

Besides, since the impurities are disposed in the silicon oxide film discretely at an atomic level, selection of the elements to be added as impurities is also a factor of key importance. The present inventors et al. took note of the fact that the nanocrystal-type semiconductor memory device as described in the Patent Documents 2 and 3 employs tungsten. Tungsten has a nature of cohesion during adhesion of tungsten on a silicon oxide film, as is described in Young, et al., Journal of Applied Physics, vol. 48, p. 3425, 1977. The nature of cohesion on a silicon oxide film suggests that there is a strong tendency that tungsten disposes nanocrystals. The present inventors et al. arrived at the conclusion that in order to achieve the semiconductor memory device as disclosed in the present invention, the element to be added to a silicon oxide film should be those elements which tend to combine with the oxygen contained in the silicon oxide film. Creation of combination with the oxygen contained in the silicon oxide film enables disposition of discrete charge trapping sites which adhere to the silicon oxide film without cohesion at an atomic level and to which the present invention is directed. Further studies have revealed the fact that adoption of metals such as titanium, zirconium and hafnium as an element that tends to combine with the oxygen contained in the silicon oxide film improves discretion such that preferable retention properties can be achieved. Besides, control of the film thickness during disposition of a metal film is an important factor for disposing, discretely at an atomic level, the metal impurities in the silicon oxide film. In order to prevent metal from cohesion, it is preferable that the film thickness during disposition of a metal film is less than the thickness of a single atomic layer, or more preferably, less than 2 Angstroms; still more preferably, less than 0.5 atomic layer or 1 Angstrom.

According to the above-described explanation, in the structure of the semiconductor memory device as defined in the present invention, electric charge trapping sites discrete at an atomic level can be disposed in a silicon oxide film. To be more specific, employment of an element that tends to combine with oxygen in a silicon oxide film allows for achievement of discreteness at an atomic level. This makes it possible to restrict the exchange, of electric charges among the charge trapping sites, and thereby to suppress loss of 2-bit information during retention in an elevated temperature condition. Besides, addition of impurities at an atomic level allows for significant reduction in the absolute quantity of the impurities to be added into the oxide film, thus facilitating improvement in the film quality of the silicon oxide film that surrounds the impurities. The silicon oxide film having an improved film quality enhances reliability of the semiconductor memory device, allows for reduction in the EOT, and thereby the high-speed reading is achieved, which is the original intent of the invention.

### First Embodiment

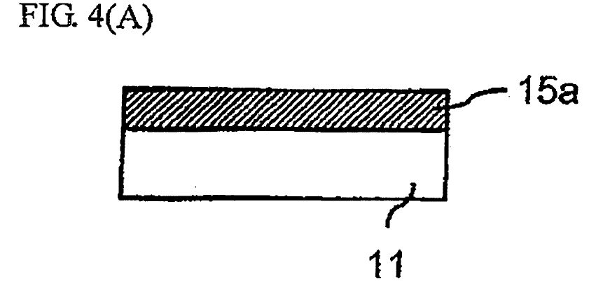

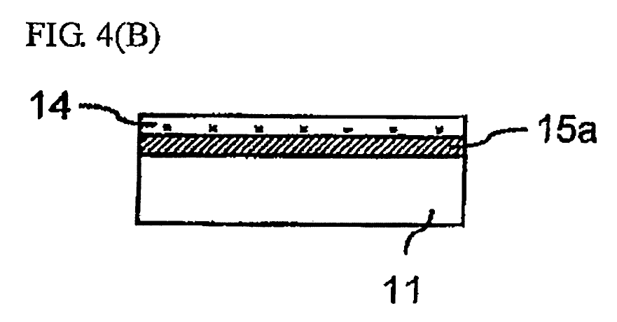

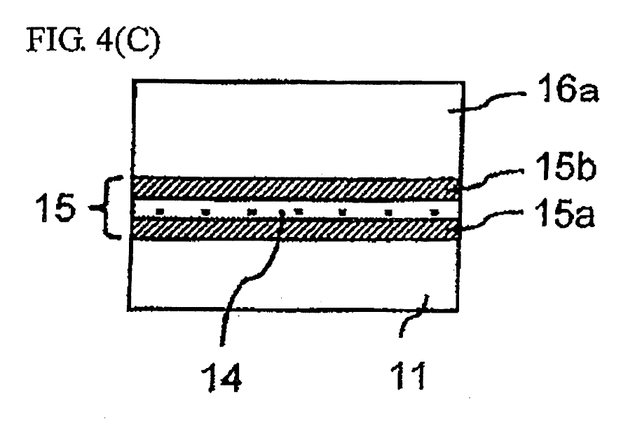

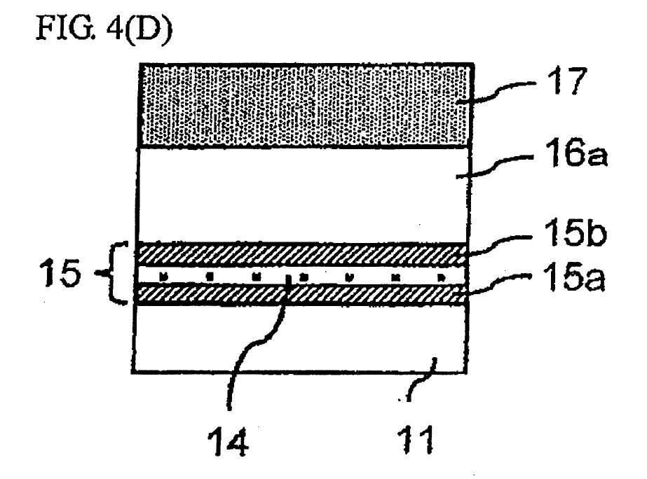

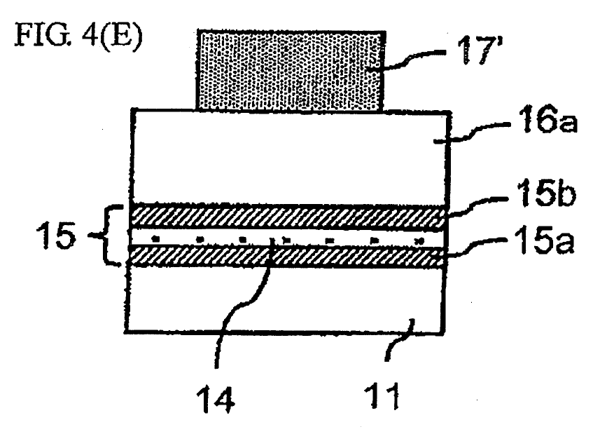

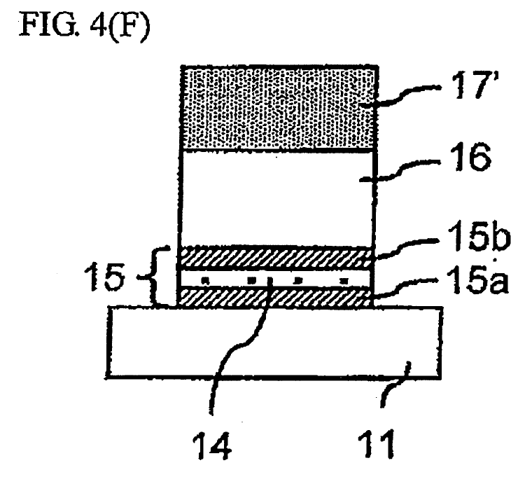

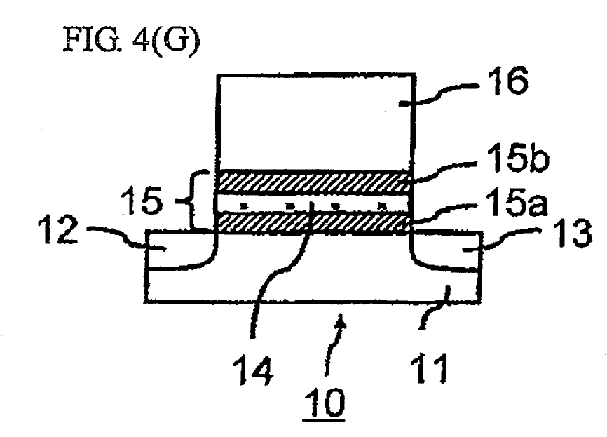

FIG. 4 is a cross-sectional view showing the method for producing the semiconductor memory device 10 according to the first embodiment of the present invention. As shown in FIG. 4(G), the semiconductor memory device 10 comprises: a semiconductor substrate 11; a first and a second impurities diffusion layers 12 and 13 disposed in the semiconductor substrate 11; a gate insulating film 15 disposed on the semiconductor substrate 11, and having a silicon oxide film 14 sandwiched between parts of the gate insulating film 15a and 15b, the silicon oxide film 14 tending to combine with the oxygen in the silicon oxide film and containing impurities discrete at an atomic level; and a first gate electrode 16 disposed on the semiconductor substrate 11 by way of the gate insulating film 15. Meanwhile, when using the parts of the gate insulating film 15a and 15b that dispose the gate insulating film 15 other than the silicon oxide film 14, not being limited to silicon oxide film, that contains impurities which tend to combine with oxygen in the silicon oxide film and which are discrete at an atomic level, the parts of the gate insulating film 15a and 15b should be of an insulating material that can dispose a potential barrier which prevents breakaway of the electric charges stored in the silicon oxide film 14 containing impurities discrete at an atomic level. The important point is that the gate insulating film 15 includes a silicon oxide film 14 that contains impurities which tend to combine with oxygen in the silicon oxide film and which are discrete at an atomic level, whereas examples of the material for the gate insulating film 15 that sandwiches the silicon oxide film 14 that contains impurities which tend to combine with oxygen in the silicon oxide film and which are discrete at an atomic level include a silicon oxide film, a high dielectric constant insulating film, and a combination thereof.

Firstly, a semiconductor substrate 11 is prepared by way of a method that is well-known from the conventional integrated circuit. Examples of the suitable material for the semiconductor substrate 11 include silicon and Silicon on Insulator. On the semiconductor substrate 11 is disposed the part of the gate insulating film 15a by way of a well-known method [FIG. 4(A)]. Suppose that silicon or Silicon on Insulator is used as material for the semiconductor substrate 11, the silicon oxide film disposed by thermal oxidizing of the semiconductor substrate 11 is preferable for the part of the gate insulating film 15a. In addition, the silicon oxide film can be used for a silicon-acid nitride film to which a slight amount of nitrogen is added, a high-dielectric constant insulating film and the like. However, in case of a high-dielectric constant insulating film, an insulating film with greater bandgap is preferred. More specifically, the high-dielectric constant insulating film preferably has a voltage of equal to and greater than 5 electron volts; for example, alumina is preferred. In case of alumina, the Chemical Vapor Deposition using a raw material gas is preferred. Besides, a laminate structure of the above-described silicon oxide film or high-dielectric constant insulating film is also applicable. The part of the gate insulating film 15a can be equal to and greater than 4 nanometers in film thickness.

Next, a silicon oxide film 14 is disposed that contains impurities which tend to combine with oxygen in a silicon oxide film and which are discrete at an atomic level. In case where the part of the gate insulating film 15a is a silicon oxide film, the impurities are deposited directly over the silicon oxide film in a vacuum chamber. In case where the part of the gate insulating film 15a is other than a silicon oxide film, a thin silicon oxide film is deposited and then the impurities are deposited thereover in a vacuum chamber. For production of a thin silicon oxide film, a film disposition method such as the Chemical Vapor Deposition using monosilane gas and/or N₂O gas was preferable, where the film thickness of approximately 0.2 to 1.5 nanometers was sufficient. The approach suitable for deposition of impurities was to control the impurities deposition quantity such as vacuum vapor deposition and sputtering. The deposited impurities were distributed in the silicon oxide film within the range of 0.2 to 1.5 nanometers deep. Although depending on the elements to be deposited, the impurities are preferably ones that can discretely exist on the silicon oxide film, and especially, the obtained results were favorable when the impurities consisted of metal. Among the metals, it turned out that titanium, zirconium and hafnium showed an excellent discreteness. The impurities deposition quantity was regulated such that the density of the charge trapping sites disposed by the impurities is equal to and greater than 1×10¹² particles/cm² and less than 1×10¹⁴ particles/cm². For example, in case where titanium is employed, and suppose that the deposition quantity is 0.4 Angstroms, the density of the charge trapping sites was approximately 7×1012 particles/cm². The impurities deposition steps led to disposition of a silicon oxide film 14 that contains impurities which tend to combine with oxygen in a silicon oxide film and which are discrete at an atomic level [FIG. 4(B)].

On the silicon oxide film 14 that contains impurities discrete at an atomic level is disposed the part of the gate insulating film 15b and a gate electrode material layer 16a [FIG. 4(C)]. The part of the gate insulating film 15b, having a thickness of, for example, equal to and greater than 5 nanometers, is sufficient for functioning as a non-volatile semiconductor memory device. In case of a silicon oxide film, a film disposition method such as the Chemical Vapor Deposition using monosilane gas and/or N₂O gas was preferable. In addition, a silicon-acid nitride film to which a slight amount of nitrogen is added, a high-dielectric constant insulating film and the like can also be used for the material for the part of the gate insulating film 15a. However, in case of a high-dielectric constant insulating film, an insulating film with greater bandgap is preferred. More specifically, the high-dielectric constant insulating film preferably has a voltage of equal to and greater than 5 electron volts; for example, alumina is preferred. In case of alumina, the Chemical Vapor Deposition using a raw material gas is preferred. Besides, a laminate structure of the above-described silicon oxide film or high-dielectric constant insulating film is also applicable. Examples of the preferable materials for a gate electrode material layer 16a include: polysilicon disposed by a monosilane gas; and metal or metallic silicide disposed by the sputtering technique, where the film thickness of equal to and greater than 50 namometers was sufficient.

In order to fabricate the gate insulating film 15 comprising the part of the gate insulating film 15a disposed on the silicon substrate 11, the silicon oxide film 14 containing impurities discrete at an atomic level, and the part of the gate insulating film 15b, and to fabricate the gate electrode material layer 16a disposed on the silicon substrate 11 through the gate insulating film 15, a photoresist 17 was disposed on the gate electrode material layer 16a [FIG. 4(D)]. The photoresist 17 was exposed by means of the optical exposure using a conventional mask, and a desired gate pattern-like photoresist 17′ was disposed by means of the processing procedure [FIG. 4(E)]. By use of the gate pattern-like photoresist 17′, the gate insulating film 15 comprising the part of the gate insulating film 15a disposed on the silicon substrate 11, the silicon oxide film 14 containing impurities, and the part of the gate insulating film 15b was fabricated, and the gate electrode material layer 16a disposed on the silicon substrate 11 through the gate insulating film 15 was fabricated. Dry etching or wet etching is optimal for the fabrication. In this way, the gate insulating film 15 comprising the part of the gate insulating film 15a disposed on the silicon substrate 11, the silicon oxide film 14 containing impurities, and the part of the gate insulating film 15b were fabricated, and the gate electrode material layer 16a disposed on the silicon substrate 11 through the gate insulating film 15 was disposed [FIG. 4(F)]. Ion injection was conducted to the fabricated gate insulating film 15 comprising the part of the gate insulating film 15a disposed on the silicon substrate 11, the silicon oxide film 14 containing impurities, and the part of the gate insulating film 15b, and to the fabricated gate electrode material layer 16a disposed on the silicon substrate 11 through the gate insulating film 15, whereby the first and second impurities diffusion layers 12 and 13 were disposed in the semiconductor substrate 11 [FIG. 4(G)].

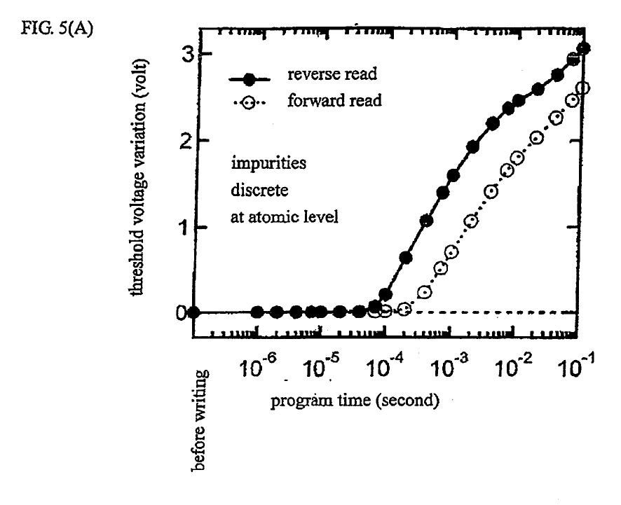

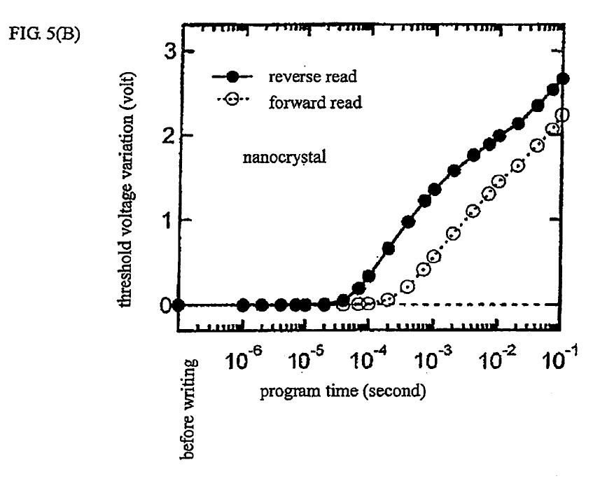

In the semiconductor memory device 10 according to the first embodiment of the present invention disposed in the above-described approach, a CHE writing was conducted at the gate voltage of 6V where the drain and source voltages were set to be 4V and 0V, respectively. Then, the threshold voltage of the semiconductor memory device 10 changed in the form of a function of the write pulse width (program time) as shown in FIG. 5(A). It is clear that the above-described reverse read threshold voltage (black circle) changes first, and then follows the increase of the forward read threshold voltage (white circle). This demonstrated the fact that a local writing was possible in the semiconductor memory device 10 according to the first embodiment of the present invention. Meanwhile, the write properties (threshold voltage variation versus write pulse width) is indicated in FIG. 4(B) in case where the disposition process equivalent to the semiconductor memory device 10 is applied, where the impurities are not disposed not discretely at an atomic level but are introduced in the form of nanocrystals. In this case, too, the above-described reverse read threshold voltage (black circle) changes first, and then follows the increase of the forward read threshold voltage (white circle). Hence, a local writing is possible even in a nanocrystal-type semiconductor memory device. As is clear from the comparison of FIGS. 5(A) and 5(B), no significant difference in the write properties is observed even when applying impurities discrete at an atomic level and when applying nanocrystals. Rather, it is clear that in the case where impurities discrete at an atomic level are applied [FIG. 5(A)], the write quantity (threshold voltage variation) increases in spite of the fact that the absolute quantity of the adhered impurities is smaller.

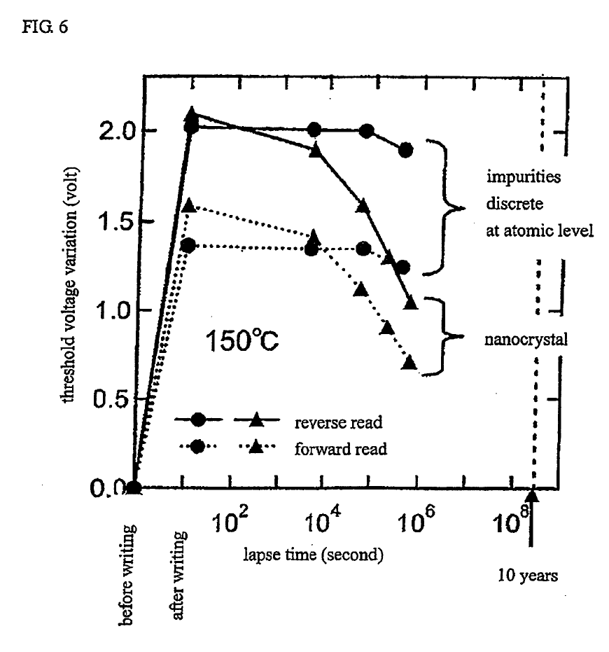

Further, in the retention test of the memory device 10 according to the first embodiment of the present invention at 150 degrees Centigrade, the threshold voltage of a write cell did not change so much, as indicated by black circles in FIG. 6. On the other hand, in the retention test where nanocrystals are disposed, the threshold voltage of a write cell significantly drops, as indicated by black triangles in the FIG. 6. Through further studies of the details, it was found that the drop of threshold of nanocrystals involves lateral diffusion of electric charges, and that the improvement in the retention capacity at 150 degrees Centigrade where impurities discrete at an atomic level is contained is due to restriction of the lateral diffusion of electric charges. Besides, since the threshold voltage of the non-write cell did not change at all, it was discovered that in case where impurities discrete at an atomic level is contained in the silicon oxide film, the write information can be read satisfactorily even after ten-year lapse. Accordingly, it was demonstrated that the semiconductor memory device 10 according to the first embodiment of the present invention had sufficient retention capacity at 150 degrees Centigrade in comparison with a nanocrystal-type semiconductor memory device.

Further, in the semiconductor memory device 10 according to the first embodiment of the present invention, it was determined that the quantity of impurities to be added was so small at an atomic level that the influence to be given to the film quality of the oxide film surrounding the impurities was quite small in comparison with the conventional case where nanocrystals were applied. This made it possible to reduce the film thickness of the silicon oxide film 15b disposed on the silicon oxide film 14 that contains impurities which tend to combine with oxygen in a silicon oxide film disposed on the semiconductor substrate 11 and which are discrete at an atomic level. In the case of nanocrystals, the silicon oxide film 15b having the thickness of 10 nanometers was not sufficient, while the semiconductor memory device 10 according to the first embodiment of the present invention could realize reduction of the film thickness of the silicon oxide film 15b as thin as 5 nanometers, allowing for achieving high ON-current and thereby achieving high-speed reading.

### Second Embodiment

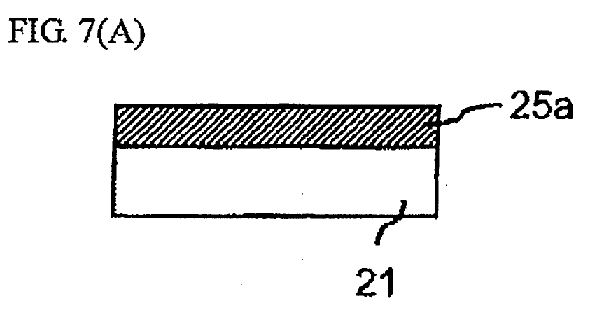

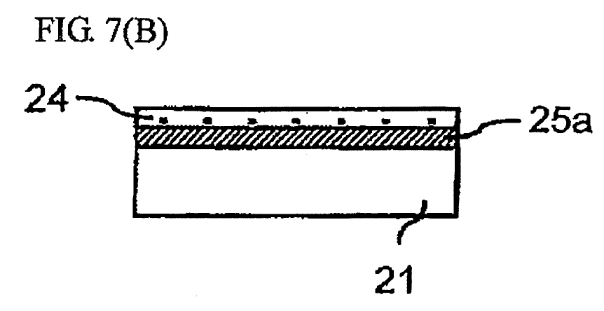

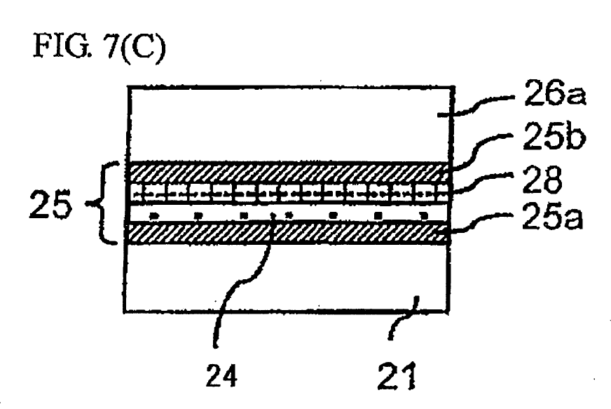

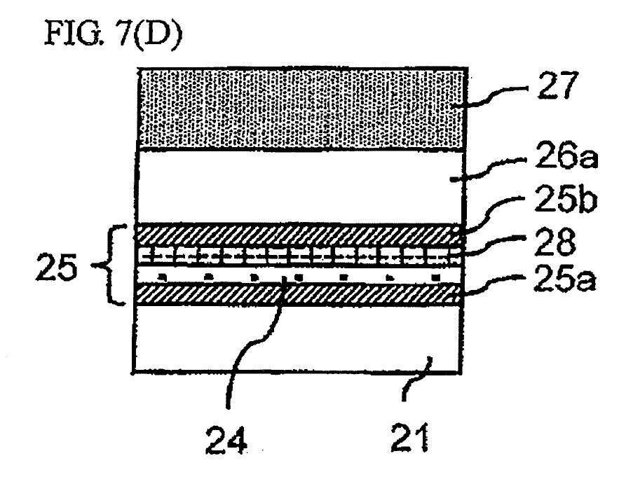

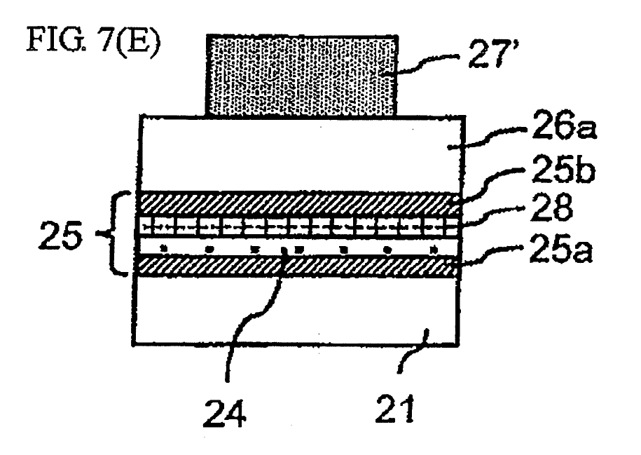

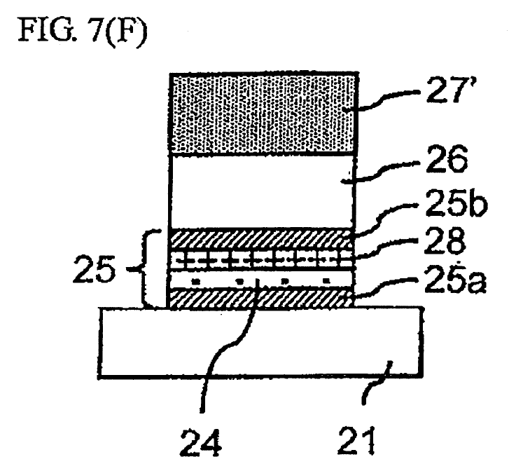

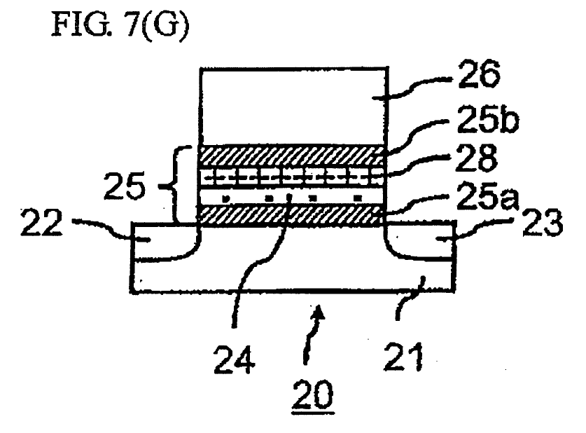

FIG. 7 is a cross-sectional view showing the method for producing the semiconductor memory device 10 according to the second embodiment of the present invention. As shown in FIG. 7(G), the semiconductor memory device 20 comprises: a semiconductor substrate 21; a first and second impurities diffusion layers 22 and 23 disposed in the semiconductor substrate 21; a gate insulating film 25 disposed on the semiconductor substrate 21, the gate insulating film 25 including a two-layer structure that comprises: a silicon oxide film 24 that contains the first impurities which tend to combine with oxygen in a silicon oxide film disposed on the semiconductor substrate 21 and which are discrete at an atomic level; and a second silicon oxide film 28 disposed thereon that contains the second impurities different from the first impurities, the two-layer structure being sandwiched between a part of the gate insulating film 25a and a part of the gate insulating film 25b; and a first gate electrode 26 disposed on the semiconductor substrate 21 by way of the gate insulating film 25. Meanwhile, when using the parts of the gate insulating film 25a and 25b that dispose the gate insulating film 25 other than: the silicon oxide film 24 that contains the first impurities discrete at an atomic level; and the second silicon oxide film 28 disposed thereon that contains the second impurities different from the first impurities, the parts of the gate insulating film 25a and 25b should be of an insulating material that can dispose a potential barrier which prevents breakaway of the electric charges stored in the silicon oxide film 24 that contains impurities which tend to combine with oxygen in the silicon oxide film and which are discrete at an atomic level. The important point is that the gate insulating film 25 includes a two-layer structure comprising: a silicon oxide film 24 that contains first impurities discrete at an atomic level; and a second silicon oxide film 28 disposed thereon that contains the second impurities different from the first impurities, whereas examples of the material for the parts of the gate insulating film 25a and 25b that sandwich the two-layer structure comprising the silicon oxide film 24 that contains the first impurities and the second silicon oxide film 28 that contains the second impurities include a silicon oxide film, a high dielectric constant insulating film, and a combination thereof.

Firstly, a semiconductor substrate 21 is prepared by way of a method that is well-known from the conventional integrated circuit. Examples of the suitable material for the semiconductor substrate 21 include silicon and Silicon on Insulator. On the semiconductor substrate 21 is disposed the part of the gate insulating film 25a by way of a well-known method [FIG. 7(A)]. Suppose that silicon or Silicon on Insulator is used as material for the semiconductor substrate 21, the silicon oxide film disposed by thermal oxidizing the semiconductor substrate 21 is preferable for the part of the gate insulating film 25a. In addition, a silicon-acid nitride film to which a slight amount of nitrogen is added, a high-dielectric constant insulating film and the like can also be used for the material for the part of the gate insulating film 15a. However, in case of a high-dielectric constant insulating film, an insulating film with greater bandgap is preferred. More specifically, the high-dielectric constant insulating film preferably has a voltage of equal to and greater than 5 electron volts; for example, alumina is preferred. In case of alumina, the Chemical Vapor Deposition using a raw material gas is preferred. Besides, a laminate structure of the above-described silicon oxide film or high-dielectric constant insulating film is also applicable. The part of the gate insulating film 25a can be equal to and greater than 4 nanometers in film thickness.

Next, a silicon oxide film 24 is disposed that contains first impurities which tend to combine with oxygen in a silicon oxide film and which are discrete at an atomic level. In case where the part of the gate insulating film 25a is a silicon oxide film, the first impurities are deposited directly over the silicon oxide film in a vacuum chamber. In case where the part of the gate insulating film 25a is other than a silicon oxide film, a thin silicon oxide film is deposited and then the first impurities are deposited thereover in a vacuum chamber. For production of a thin silicon oxide film, a film disposition method such as the Chemical Vapor Deposition using monosilane gas and/or N₂O gas was preferable, where the film thickness of approximately 0.2 to 1.5 nanometers was sufficient. The approach suitable for deposition of the first impurities was to control the impurities deposition quantity such as vacuum vapor deposition and sputtering. The deposited first impurities were distributed in the silicon oxide film within the range of 0.2 to 1.5 nanometers deep. Although depending on the elements to be deposited, the first impurities are preferably one that can discretely exist on the silicon oxide film, and especially, the obtained results were favorable when the impurities consisted of metal. Among the metals, it turned out that titanium, zirconium and hafnium showed an excellent discreteness. The first impurities deposition quantity was regulated such that the density of the charge trapping sites disposed by the first impurities was equal to and greater than 1×10¹² particles/cm² and less than 1×10¹⁴ particles/cm². For example, in case where titanium was employed, and suppose that the deposition quantity was 0.4 Angstroms, the density of the charge trapping sites was approximately 7×1012 particles/cm². The first impurities deposition steps led to disposition of a silicon oxide film 14 that contained the first impurities which tended to combine with oxygen in a silicon oxide film and which were discrete at an atomic level [FIG. 6(B)]. On the silicon oxide film 24 that contains the first impurities is deposited a second silicon oxide film 28 that contains second impurities different from the first impurities. Excellent properties can be observed when nitrogen was used for the second impurities, where the density of the nitrogen was approximately 0.1 to 10%, for example. The thickness of the second silicon oxide film 28 that contains the second impurities can be approximately 0.5 to 2 nanometers. Meanwhile, there are methods for depositing the second silicon oxide film 28 wherein: a silicon oxide film is first disposed and then the second impurities are introduced; and a silicon oxide film that contains the second impurities is directly disposed. The conceivable examples of the former include the Chemical Vapor Deposition using monosilane gas and/or N₂O gas, the Chemical Vapor Deposition using a gas such as TEOS, and the sputtering technique that targets the silicon oxide film. In case where the second impurities were nitrogen, it was preferable to adopt the method for introducing nitrogen by heat treatment in an ammonium-gas atmosphere, and by exposure to inside the nitrogen plasma. When the second impurities are of other elements, the preferable method was the sputtering technique and the like.

On the two-layer structure comprising: a silicon oxide film 24 that contains first impurities discrete at an atomic level; and a second silicon oxide film 28 disposed thereon that contains the second impurities, is disposed the part of the gate insulating film 25b and a gate electrode material layer 26a [FIG. 7(C)]. The part of the gate insulating film 25b, having a thickness of, for example, equal to and greater than 5 nanometers, is enough for functioning as a non-volatile semiconductor memory device. In case of a silicon oxide film, a film disposition method such as the Chemical Vapor Deposition using monosilane gas and/or N₂O gas was preferable. In addition, a silicon-acid nitride film to which a slight amount of nitrogen is added, a high-dielectric constant insulating film and the like can also be used for the material for the part of the gate insulating film 25b. However, in case of a high-dielectric constant insulating film, an insulating film with greater bandgap is preferred. More specifically, the high-dielectric constant insulating film preferably has a voltage of equal to and greater than 5 electron volts; for example, alumina is preferred. In case of alumina, the Chemical Vapor Deposition using a raw material gas is preferred. Besides, a laminate structure of the above-described silicon oxide film or high-dielectric constant insulating film is also applicable. Examples of the preferable materials for a gate electrode material layer 26a include: polysilicon disposed by a monosilane gas; and metal or metallic silicide disposed by the sputtering technique, where the film thickness of equal to and greater than 50 nanometers was sufficient.

In order to fabricate the gate insulating film 25 comprising the part of the gate insulating film 25a disposed on the silicon substrate 21, the silicon oxide film 24 containing the first impurities, the second silicon oxide film 28 containing the second impurities, and the part of the gate insulating film 25b, and to fabricate the gate electrode material layer 26a disposed on the silicon substrate 21 through the gate insulating film 25, a photoresist 27 was disposed on the gate electrode material layer 26a [FIG. 7(D)]. The photoresist 2, V was exposed by means of the optical exposure using a conventional mask, and a desired gate pattern-like photoresist 27′ was disposed by means of the processing procedure [FIG. 6(E)]. By use of the gate pattern-like photoresist 27′ f, the gate insulating film 25 comprising the part of the gate insulating film 25a disposed on the silicon substrate 21, the silicon oxide film 24 containing the first impurities, the second silicon oxide film 28 containing the second impurities, and the part of the gate insulating film 25b was fabricated, and the gate electrode material layer 26a disposed on the silicon substrate 21 through the gate insulating film 25 was fabricated. Dry etching or wet etching is optimal for the fabrication. In this way, the gate insulating film 25 comprising the part of the gate insulating film 25a disposed on the silicon substrate 21, the silicon oxide film 24 and the part of the gate insulating film 15b was fabricated, and the gate electrode material layer 16a disposed on the silicon substrate 11 through the gate insulating film 15 was disposed [FIG. 4(F)]. Ion injection was conducted to the fabricated gate insulating film 25, and to the first gate electrode 26 disposed on the silicon substrate 21 through the gate insulating film 25, whereby the first and second impurities diffusion layers 22 and 23 were disposed in the semiconductor substrate 21 [FIG. 7(G)].

In the semiconductor memory device 20 according to the second embodiment of the present invention disposed in the above-described approach, a CHE writing was conducted at the gate voltage of 6V where the drain and source voltages were set to be 4V and 0V, respectively, and it was found that local writing was possible.

Further, in the retention test of the memory device 20 according to the second embodiment of the present invention at 150 degrees Centigrade, the threshold voltage of a write cell did not change so much. On the other hand, in the retention test where nanocrystals were disposed, the threshold voltage of a write cell significantly dropped. It was thus discovered that in case where impurities discrete at an atomic level was contained in the silicon oxide film, the write information could be read satisfactorily even after ten-year lapse. Accordingly, it was demonstrated that the semiconductor memory device 20 according to the second embodiment of the present invention had sufficient retention capacity at 150 degrees Centigrade.

Further, in the semiconductor memory device 20 according to the second embodiment of the present invention, it was determined that the quantity of the first impurities to be added is so small at an atomic level that the influence to be given to the film quality of the oxide film surrounding the first impurities is quite small in comparison with the conventional case where nanocrystals are applied. Besides, it also turned out that disposition of the second silicon oxide film 28 containing the second impurities would further reduce the influence of the first impurities toward the quality of the oxide film surrounding the first impurities. This made it possible to reduce the film thickness of the part of the gate insulating film (silicon oxide film) 25b disposed on the two-layer structure comprising: the silicon oxide film 24 that contains the first impurities which tend to combine with oxygen in a silicon oxide film and which are discrete at an atomic level; and the second silicon oxide film 28 that is disposed on the silicon oxide film 24 and that contains the second impurities different from the first impurities. In the case of nanocrystals, the silicon oxide film 25b having the thickness of 10 nanometers was not sufficient, while the semiconductor memory device 20 according to the second embodiment of the present invention could realize reduction of the film thickness of the silicon oxide film 25b as thin as 4 nanometers, allowing for achieving high ON-current and thereby achieving high-speed reading.

### Third Embodiment

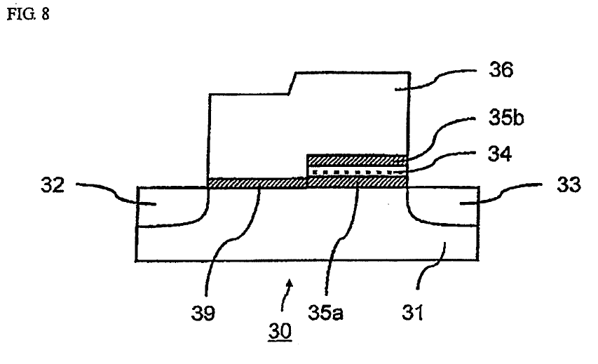

FIG. 8 is a structure cross-sectional view showing the semiconductor memory device 30 according to the third embodiment of the present invention. Meanwhile, in the present embodiment, the silicon oxide film 34 that contains impurities which tend to combine with oxygen in the silicon oxide film and which are discrete at an atomic level is described only in the form of a silicon oxide film wherein the entire gate insulating film is disposed of a silicon oxide film; however, the other aspects of the gate insulating film structure is also acceptable. The same applies to the following embodiments. As shown in FIG. 8, the semiconductor memory device 30 comprises: a semiconductor substrate 31; a first impurities diffusion layer 32 and a second impurities diffusion layer 33 disposed in the semiconductor substrate 31; a gate insulating film disposed on the semiconductor substrate 31, and a first gate electrode 36 disposed on the semiconductor substrate 31 by way of the gate insulating film. In the present embodiment, the first gate electrode 36 is disposed to straddle a gate insulating film and a second gate insulating film 39, the gate insulating film comprising: a part of the gate insulating film 35a disposed by the silicon oxide film; a silicon oxide film 34 disposed on the part of the gate insulating film 35a, the silicon oxide film 34 containing impurities which tend to combine with oxygen in a silicon oxide film disposed on the semiconductor substrate 11 and which are discrete at an atomic level; and a part of the gate insulating film 35b that is disposed on the silicon oxide film 34 containing impurities and that is disposed by the silicon oxide film, and the second gate insulating film 39 not including the silicon oxide film 34 that contains impurities discrete at an atomic level. The silicon oxide film having the silicon oxide film 34 that contains discrete impurities is disposed closer to one of the source and drain regions, whereas the second gate insulating film 39 is disposed closer to the other one of the source and drain regions.

### Fourth Embodiment

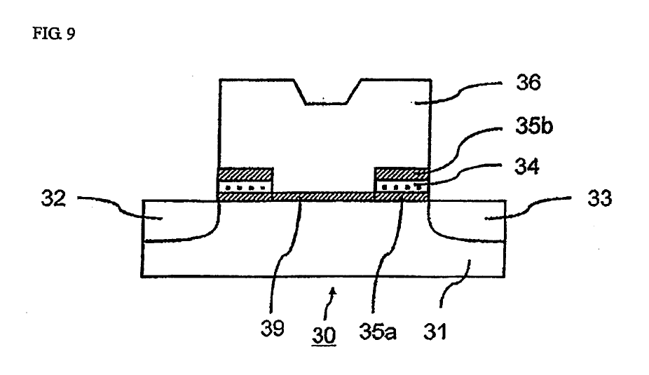

FIG. 9 is a structure cross-sectional view showing the semiconductor memory device 30 according to the fourth embodiment of the present invention. In FIG. 9, the parts equivalent to those in FIG. 8 that represents the third embodiment are assigned the same reference numerals, and thus, the redundant descriptions will be omitted for brevity. In the present embodiment, a first gate electrode 36 is disposed to straddle a gate insulating film and a second gate insulating film 39, the gate insulating film having a silicon oxide film 34 that contains impurities which tend to combine with oxygen in the silicon oxide film and which are discrete at an atomic level, and the second gate insulating film 39 not including the silicon oxide film that contains discrete impurities. The gate insulating film having the silicon oxide film 34 that contains impurities is disposed closer to the first and second impurities diffusion layer 32 and 33, whereas the second gate insulating film 39 is disposed on the central part of the channel region.

### Fifth Embodiment

FIG. 10 is a structure cross-sectional view showing the semiconductor memory device 30 according to the fifth embodiment of the present invention. In FIG. 10, the parts equivalent to those in FIG. 8 that represents the third embodiment are assigned the same reference numerals, and thus, the redundant descriptions will be omitted for brevity. In the present embodiment, a first gate electrode 36 and a second gate electrode 36′ are provided on a semiconductor substrate 31. The first gate electrode 36 is disposed on a gate insulating film having a silicon oxide film 34 that contains impurities which tends to combine with oxygen in the silicon oxide film and which are discrete at an atomic level, while the second gate electrode 36′ is disposed on the second gate insulating film 39 not including the silicon oxide film 34 that contains impurities discrete at an atomic level. Further, the second gate electrode 36′ is disposed in such a manner that a part thereof runs on the first gate electrode 36. The first gate electrode 36 and the second gate electrode 36′ are insulated by an insulating film 41, and a sidewall insulating film 40 is disposed on the side surface of the first gate electrode 36.

### Sixth Embodiment

FIG. 10 is a structure cross-sectional view showing the semiconductor memory device 30 according to the sixth embodiment of the present invention. In FIG. 10, the parts equivalent to those in FIG. 7 that represents the third embodiment are assigned the same reference numerals, and thus, the redundant descriptions will be omitted for brevity. In the present embodiment, the second gate electrode 36′ is disposed on the second gate insulating film 39 not including the silicon oxide film 34 that contains impurities discrete at an atomic level, and on both sides thereof, the first gate electrode 36 is disposed, in a sidewall-film shape, on the gate insulating film having a silicon oxide film 34 that contains impurities which tend to combine with oxygen in the silicon oxide film and which are discrete at an atomic level. The silicon oxide film 34 containing impurities discrete at an atomic level can be included in the sidewall insulating film 40 provided between the first gate electrode 36 and the second gate electrode 36′. Meanwhile, the more preferable aspect is that the impurities contained in the sidewall insulating film 40 are either inhibited or eliminated. A way to achieve this is, for example, to use a sputter having directivity such that the impurities will be included only on the bottom surface of the silicon oxide film.

In the above-described semiconductor memory device according to each of the third to sixth embodiments of the present invention, too, the experimental results were favorable, in particular, when metal was used as the impurities which tend to combine with oxygen in the silicon oxide film and which are discrete at an atomic level. Among the metals, excellent discreteness could be observed when titanium, zirconium and hafnium was used. The preferable impurities deposition quantity was regulated such that the density of the charge trapping sites disposed by the impurities is equal to and greater than 1×10¹² particles/cm² and less than 1×10¹⁴ particles/cm². Further, on the silicon oxide film 34 that contains the impurities which tend to combine with oxygen in a silicon oxide film and which are discrete at an atomic level could be deposited a second silicon oxide film that contains the second impurities, such as nitrogen, different from the aforementioned impurities.

In the above-described semiconductor memory device according to each of the third to sixth embodiments of the present invention, too, a semiconductor memory device could be achieved that can fully restrict the lateral diffusion of the electric charges and has an excellent retention capacity at an elevated temperature, in comparison with the MONOS-type semiconductor memory devices which employ conventional nanocrystals.

Further, the above-described semiconductor memory device according to each of the first to sixth embodiments of the present invention is arranged on a matrix such that a memory array is configured. This memory array can be mounted with a logic circuit or a logic memory and other memory (such as DRAM and SRAM), and also can be used for an IC dedicated for non-volatile memory. Meanwhile, in order to use it as a non-volatile semiconductor memory device that can operate in an elevated temperature condition, the thickness of the gate insulating film or the silicon oxide film arranged on both sides of the silicon oxide film that is a charge storing layer, that contains impurities which tend to combine with oxygen in a silicon oxide film disposed on the semiconductor substrate and which are discrete at an atomic level is preferably equal to and greater than 4 nanometers. On the contrary, in order to use as a non-volatile semiconductor memory device that can operate at a temperature of approximately 85 degrees Centigrade, or as a new type of semiconductor memory device that is not non-volatile but can conduct a high-speed write and erase operations and that has a longer retention capacity than a conventional DRAM does, the thickness of the gate insulating film or the silicon oxide film could be 4 nanometers or smaller.

The present invention can be applied to anything that is directed to a semiconductor memory device and a semiconductor device, and more particularly to a semiconductor memory device that can retain information by trapping electric charges into a trap level in a gate insulating film, and to a semiconductor device in which the semiconductor memory device is mounted, and the availability thereof is not limited at all.

The invention has been described in detail with reference to certain preferred embodiments thereof, but it will be understood that these embodiments are intended just for describing the invention with specific examples thereof and not for limiting the invention. It should be clear that any skilled person, after reading the present specification, could make modifications or substitutions using equivalent components and technologies. However, it should also be clear that such modifications or substitutions would still be covered by the true scope and spirit of the appended Claims.

1-27. (canceled)

28. A semiconductor memory device that conducts a memory operation by trapping electric charges into a gate insulating film, wherein
the gate insulating film has a first insulating film that contains first impurities which tend to combine with oxygen in the insulating film and which are discrete at an atomic level.

29. A semiconductor memory device that conducts a memory operation by trapping electric charges into a gate insulating film, the semiconductor memory device comprising:
a semiconductor substrate;
first and second impurities diffusion layers disposed in the semiconductor substrate;
a gate insulating film disposed on the semiconductor substrate; and
a first gate electrode disposed on the semiconductor substrate by way of the gate insulating film,
wherein the gate insulating film has a first insulating film that contains first impurities which tend to combine with oxygen in the insulating film and which are discrete at an atomic level.

30. A semiconductor memory device that conducts a memory operation by trapping electric charges into a gate insulating film, the semiconductor memory device comprising:
a semiconductor substrate;
first and second impurities diffusion layers disposed in the semiconductor substrate;
a gate insulating film disposed on the semiconductor substrate; and
a first gate electrode disposed on the semiconductor substrate by way of the gate insulating film,
wherein the gate insulating film has:
a first insulating film that contains first impurities which tend to combine with oxygen in the insulating film and which are discrete at an atomic level; and
on a top and a bottom of the first insulating film, a silicon oxide film that does not contain the first impurities.

31. A semiconductor memory device that conducts a memory operation by trapping electric charges into a gate insulating film, the semiconductor memory device comprising:
a semiconductor substrate;
first and second impurities diffusion layers disposed in the semiconductor substrate;
a gate insulating film disposed on the semiconductor substrate; and
a first gate electrode disposed on the semiconductor substrate by way of the gate insulating film,
wherein the gate insulating film has:
a first insulating film that contains first impurities which tend to combine with oxygen in the insulating film and which are discrete at an atomic level; and
a second insulating film that contains second impurities different from the first impurities, the second insulating film being disposed immediately on a top of the first insulating film.

32. A semiconductor memory device that conducts a memory operation by trapping electric charges into a gate insulating film, the semiconductor memory device comprising:
a semiconductor substrate;
first and second impurities diffusion layers disposed in the semiconductor substrate;
a gate insulating film disposed on the semiconductor substrate; and
a first gate electrode disposed on the semiconductor substrate by way of the gate insulating film,
wherein the gate insulating film has:
a first insulating film that contains first impurities which tend to combine with oxygen in the insulating film and which are discrete at an atomic level;
a second insulating film that contains second impurities different from the first impurities, the second insulating film being disposed immediately on a top of the first insulating film; and further
a silicon oxide film disposed on a top and a bottom of a deposited film comprised of the first and second insulating films, the silicon oxide film not containing the first and second impurities.

33. The semiconductor memory device as defined in claim 28, wherein a density of charge trapping sites disposed by the first impurities is equal to and greater than 1×10¹² particles/cm² and less than 1×10¹⁴ particles/cm².

34. The semiconductor memory device as defined in claim 28, wherein the first impurities consist of metal.

35. The semiconductor memory device as defined in claim 28, wherein the first impurities consist of titan.

36. The semiconductor memory device as defined in claim 34, wherein the addition quantity of the first impurities as converted to film thickness of metal is less than the thickness of a single atomic layer.

37. The semiconductor memory device as defined in claim 29, wherein the second impurities consist of nitrogen.

38. The semiconductor memory device as defined in claim 28, wherein the first insulating film consists of, or the first and second insulating films consist of, silicon oxide film.

39. The semiconductor memory device as defined in claim 28, wherein a thin film consists of Al₂O₃, SiN or SiON is disposed on the first insulating film.

40. The semiconductor memory device as defined in claim 31, wherein a thin film consists of Al₂O₃, SiN or SiON is disposed on the first or second insulating film.

41. The semiconductor memory device as defined in claim 28, wherein at least a part of the gate insulating film is comprised of a dielectric constant insulating film.

42. The semiconductor memory device as defined in claim 28, wherein at least a part of the gate insulating film is comprised of a deposited layer structure that consists of silicon oxide film-silicon nitride film-silicon oxide film.

43. The semiconductor memory device as defined in claim 29, wherein a distance between the first insulating film and the semiconductor substrate is equal to and greater than 4 nanometers.

44. The semiconductor memory device as defined in claim 28, wherein a distance between the first insulating film and the gate electrode is equal to and greater than 4 nanometers.

45. The semiconductor memory device as defined in claim 31, wherein a distance between the first or second insulating film and the gate electrode is equal to and greater than 4 nanometers.

46. The semiconductor memory device as defined in claim 29, wherein an entirety of the first gate electrode is disposed on the gate insulating film.

47. The semiconductor memory device as defined in claim 31, wherein:
one part of the first gate electrode is disposed on the gate insulating film having the first insulating film; and the other part of the first gate electrode is disposed on a second gate insulating film not having the first or second impurities.

48. The semiconductor memory device as defined in claim 47, wherein:
the gate insulating film having the first insulating film is disposed closer to one of first and second impurities diffusion layers; and
the second gate insulating film is disposed closer to an other one of the first and second impurities diffusion layers.

49. The semiconductor memory device as defined in claim 47, wherein:
the second gate insulating film is disposed on the semiconductor substrate between the first and second impurities diffusion layers; and
the gate insulating film having the first insulating film is disposed on both sides thereof.

50. The semiconductor memory device as defined in claim 47, wherein:
the first and second gate electrodes are disposed on the semiconductor substrate between first and second impurities diffusion layers;
the second gate electrode is disposed on second gate insulating film that does not contain the first impurities or the first and second impurities; and
the first gate electrode is disposed on the first insulating film.

51. The semiconductor memory device as defined in claim 50, wherein the second gate electrode is disposed in such a manner that a part thereof runs on the first gate electrode.

52. The semiconductor memory device as defined in claim 50, wherein:
the second gate electrode is disposed on the semiconductor substrate between first and second impurities diffusion layer; and
the first gate electrodes are disposed on and across both sides of the second gate electrode.

53. The semiconductor memory device as defined in claim 50, wherein:
the first, second and third gate electrodes are disposed on the semiconductor substrate between the first and second impurities diffusion layers;
the second gate electrode is disposed on second gate insulating film that does not contain the first impurities or the first and second impurities; and
the first and third gate electrodes are disposed on the first insulating film.

54. The semiconductor memory device as defined in claim 50, wherein:
a first voltage equal to and greater than a specific voltage in absolute value is applied to between the first and second impurities diffusion layers disposed between the semiconductor substrate, and a second voltage equal to and greater than a specific voltage in absolute value is applied to the first gate electrode, whereby a hot carrier is generated in the vicinity of the first or second impurities diffusion layer; and
the hot carrier is locally injected to the silicon oxide film that contains impurities whereby write or erase operation is conducted.

55. The semiconductor device wherein the semiconductor memory device as defined in claim 28 is disposed on a region of a substrate, and a circuit other than a non-volatile memory is disposed on a remaining region of the substrate.

56. The semiconductor device wherein the semiconductor memory device as defined in claim 28 is disposed on a region of a substrate, and a logic circuit is disposed on a remaining region of the substrate.
